(19) United States
(12) Patent Application Publication
(10) Pub. No.: US 2014/0070297 A1
(43) Pub. Date: Mar. 13, 2014

(54) SEMICONDUCTOR STORAGE DEVICE AND FABRICATION METHOD THEREOF

(71) Applicant: KABUSHIKI KAISHA TOSHIBA, Tokyo (JP)

(72) Inventors: Hiroyuki YAMASAKI, Chiba (JP); Hisataka MEGURO, Mie (JP)

(73) Assignee: KABUSHIKI KAISHA TOSHIBA, Tokyo (JP)

(21) Appl. No.: 14/016,779

(22) Filed: Sep. 3, 2013

(30) Foreign Application Priority Data
Sep. 10, 2012 (JP) 2012-198424

(51) Int. Cl. H01L 27/105

(52) U.S. Cl. CPC H01L 27/1052
USPC 257/316; 438/586

(57) ABSTRACT

According to one embodiment, the semiconductor storage device includes a semiconductor substrate, a first pair of selection-gate electrodes including a first conductor layer and a second conductor layer, a second pair of selection-gate electrodes, a memory cell region formed in the area sandwiched by the first pair of selection-gate electrodes and the second pair of selection-gate electrodes, an interlayer-insulating film, a first contact provided between the first pair of selection gates and penetrates through the interlayer-insulating film and the first conductive film layer and is connected on the surface of the semiconductor substrate, and a second contact provided between the second pair of selection gates, in which first contact is connected to the first conductive film layer via an insulating film on the side surface thereof.

### CROSS-REFERENCE TO RELATED APPLICATION

This application is based upon and claims the benefit of priority from Japanese Patent Application No. 2012-198424, filed Sep. 10, 2012, the entire contents of which are incorporated herein by reference.

### FIELD

Embodiments described herein relate generally to a semiconductor storage device and a fabrication method thereof.

### BACKGROUND

Recently, the architecture of semiconductor storage devices evolved to have multiple memory cells arranged in a matrix pattern. Contacts are connected to the memory cells to enable electrical reading and writing of these memory cells. For example, in a NAND-type flash memory device, a selection-gate transistor is arranged at the opposed ends of a row of multiple memory cells. A contact is provided individually for each bit line between the selection-gate transistors on the drain side of the selection transistors, while a contact, used to commonly connect the multiple source sides of the selection gate transistors is formed between the selection-gate transistors on the source side.

When an interlayer-insulating film is etched to simultaneously form the opening for the contact between the selection-gate lines on the drain side and the opening for the contact between the selection gates on the source side, because the interlayer-insulating film opening on the source side, having a larger area opening, is etched faster, the opening being etched on the source side will reach the surface of the semiconductor substrate first, i.e., before the drain side opening is fully etched. When etching continues until the opening in the interlayer insulating film on the drain side reaches the semiconductor substrate, the larger source side opening requires scaling of the device region, and the isolation region in which the device is embedded, to be larger on the source side of the transistor than on the drain side. This is a problem.

Consequently, it is difficult to form the contact openings in the interlayer insulating film on the drain side and on the source side with different opening areas in one step. When separate lithographic and etching steps are used to form the drain and source side openings, the number of process steps will increase, resulting in increased costs.

### DESCRIPTION OF THE DRAWINGS

FIG. 1 is a schematic diagram illustrating an electrical configuration of a NAND-type flash memory device according to an embodiment.

FIG. 2 is a schematic plane view of the memory cell region of the NAND-type flash memory device in the embodiment.

FIG. 3 is a plane view of a resistor R formed in a peripheral circuit region of the NAND-type flash memory device in the embodiment.

FIG. 4A is a longitudinal cross-sectional view of a part indicated by line A-A in FIG. 2 in the NAND-type flash memory device in the embodiment. FIG. 4B is a longitudinal cross-sectional view of a part indicated by line B-B in FIG. 2. FIG. 4C is a longitudinal cross-sectional view of a part indicated by line E-E in FIG. 3.

FIG. 5A is a longitudinal cross-sectional view of the part indicated by line A-A in FIG. 2 in one step of the fabrication process. FIG. 5B is a longitudinal cross-sectional view of the part indicated by line B-B in FIG. 2. FIG. 5C is a longitudinal cross-sectional view of the part indicated by line E-E in FIG. 3 (Part 1).

FIG. 6A is a longitudinal cross-sectional view of the part indicated by line A-A in FIG. 2 in one step of the fabrication process. FIG. 6B is a longitudinal cross-sectional view of the part indicated by line B-B in FIG. 2. FIG. 6C is a longitudinal cross-sectional view of the part indicated by line E-E in FIG. 3 (Part 2).

FIG. 7A is a longitudinal cross-sectional view of the part indicated by line A-A in FIG. 2 in one step of the fabrication process. FIG. 7B is a longitudinal cross-sectional view of the part indicated by line B-B in FIG. 2. FIG. 7C is a longitudinal cross-sectional view of the part indicated by line E-E in FIG. 3 (Part 3).

FIG. 8A is a longitudinal cross-sectional view of the part indicated by line A-A in FIG. 2 in one step of the fabrication process. FIG. 8B is a longitudinal cross-sectional view of the part indicated by line B-B in FIG. 2. FIG. 8C is a longitudinal cross-sectional view of the part indicated by line E-E in FIG. 3 (Part 4).

FIG. 9A is a longitudinal cross-sectional view of the part indicated by line C-C in FIG. 2 of the NAND-type flash memory device in the embodiment. FIG. 9B is a longitudinal cross-sectional view of the part indicated by line D-D in FIG. 2.

FIG. 10A is a longitudinal cross-sectional view of the part indicated by line C-C in FIG. 2 in one step of the fabrication process. FIG. 10B is a longitudinal cross-sectional view of the part indicated by line D-D in FIG. 2 (Part 1).

FIG. 11A is a longitudinal cross-sectional view of the part indicated by line C-C in FIG. 2 in one step of the fabrication process. FIG. 11B is a longitudinal cross-sectional view of the part indicated by line D-D in FIG. 2 (Part 2).

FIG. 12A is a longitudinal cross-sectional view of the part indicated by line C-C in FIG. 2 in one step of the fabrication process. FIG. 12B is a longitudinal cross-sectional view of the part indicated by line D-D in FIG. 2 (Part 3).

FIG. 13A is a longitudinal cross-sectional view of the part indicated by line C-C in FIG. 2 in one step of the fabrication process. FIG. 13B is a longitudinal cross-sectional view of the part indicated by line D-D in FIG. 2 (Part 4).

### DETAILED DESCRIPTION

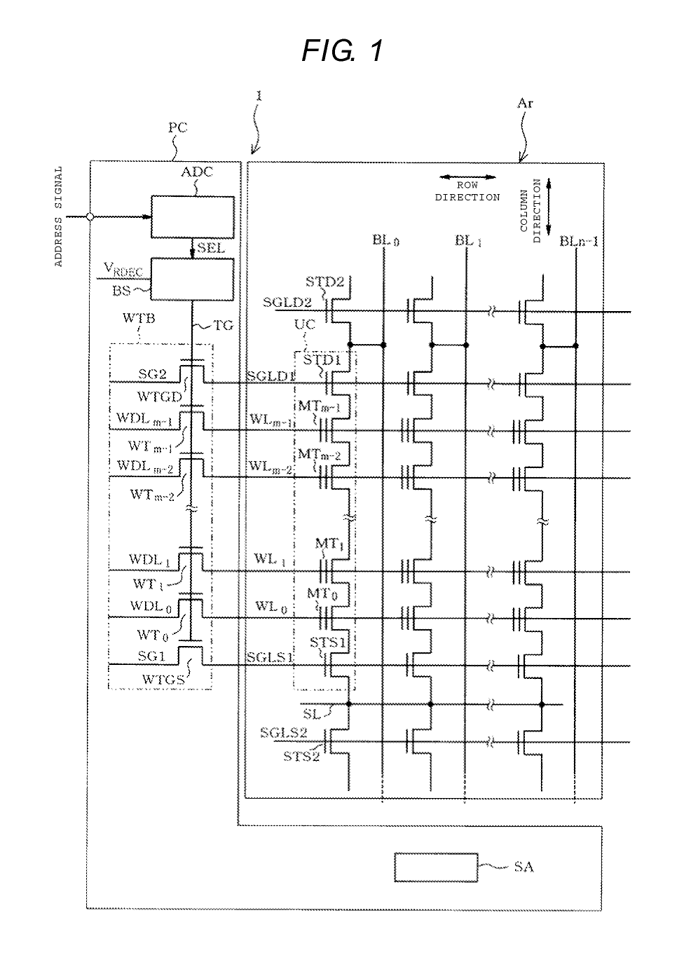

In general, according to one embodiment, the semiconductor storage device of the embodiment will be described with reference to the figures. The NAND-type flash memory device of a nonvolatile semiconductor storage device will be described as the semiconductor storage device with reference to FIGS. 1 to 13B. In the following descriptions, the constituent elements with the same function and configuration are represented by the same symbols. The figures are schematic diagrams. Therefore, the relationship between the thickness and the planar dimensions, the ratio of the thickness of each layer, and the like are not necessarily consistent with the actual ones. As far as the directions are concerned, relative directions are used in this case with the side of the circuit-forming surface on the semiconductor substrate as up. These directions are not necessarily consistent with those based on the direction of gravitational acceleration.

The semiconductor storage device of this embodiment includes a semiconductor substrate, a first pair of selection-gate electrodes including a first conductor layer and a second conductor layer, a second pair of selection-gate electrodes, a memory cell region formed in a matrix pattern in the area sandwiched by the first pair of selection-gate electrodes and the second pair of selection-gate electrodes, an interlayer-insulating film covering the first pair of the selection-gate electrodes, the second pair of selection-gate electrodes, and the memory cell region, a first contact provided between the first pair of selection gates, and a second contact provided between the second pair of selection gates. The first contact at least penetrates through the interlayer-insulating film and the first conductive film layer and is connected on the surface of the semiconductor substrate. An insulating film is formed on the first contact. The first contact is at least connected to the first conductive film layer via the insulating film on the side surface of the first contact.

According to the semiconductor storage device fabrication method of this embodiment, a first conductive film, a first insulating film, a second conductive film, and a second insulating film are formed sequentially on a semiconductor substrate having a first region, a second region, and a third region. A first electrode is formed by eliminating the second insulating film, the second conductive film, the first insulating film, and the first conductive film, in the first region. A second electrode and a third electrode are formed by eliminating the second insulating film and the second conductive film, in the second and third regions. After a sidewall conductive film is formed on the sidewall portion of the first electrode, the sidewall portion of the second electrode, and the sidewall portion of the third electrode, a fourth insulating film, a fifth insulating film, and a sixth insulating film are formed. The semiconductor storage device has a first contact-opening portion that penetrates through the sixth insulating film, the fifth insulating film, and the fourth insulating film and is connected to the surface of the semiconductor substrate in the first region, a second contact-opening portion that penetrates through the sixth insulating film, the fifth insulating film, the fourth insulating film, and the first insulating film and is connected to the surface of the first conductive film in the second region, and a third contact-opening portion that has an opening area larger than the opening area of at least the first contact-opening portion and the second contact-opening portion and penetrates through the sixth insulating film, the fifth insulating film, the fourth insulating film, the first insulating film, the first conductive film, and the gate-insulating film and is connected to the surface of the semiconductor substrate in the third region. The third contact-opening portion has an opening area that is at least bigger than the opening areas of the first contact-opening portion and the second contact-opening portion. The first, second, and third opening sections are formed in the same step.

FIG. 1 is a block diagram schematically illustrating the electrical configuration of a NAND-type flash memory device. As shown in FIG. 1, the NAND-type flash memory device 1 has a memory cell array Ar formed by arranging multiple memory cells in a matrix pattern, and a peripheral circuit PC that performs reading/writing/erasure to each memory cell in the memory cell array Ar, and an input/output interface circuit (not shown in the figure).

Multiple cell units UC are disposed in the memory cell array Ar. Each cell unit UC includes a selection-gate transistor STD1 on the bit-line side (drain side) connected to each of the bit lines BL₀-BLₙ₋₁, a source-side selection-gate transistor STS1 connected to the source line SL, and a plurality of memory cell transistors Mt₀-MTₘ₋₁ in a number of the k-th power of 2 (for example, 32 (=m)) connected in series between the two selection-gate transistors STD1 and STS1.

One block of the memory cell array has n columns of the cell units UC arranged side by side in the row direction (horizontal, or left to right direction in FIG. 1). The memory cell array Ar is formed by arranging multiple blocks of cell units in the column direction (vertical direction in FIG. 1). To simplify the description, only one block of cell units is shown in FIG. 1.

A peripheral circuit region is provided on the periphery of the memory cell region. The peripheral circuit PC is arranged on the periphery of the memory cell array Ar. The peripheral circuit PC has an address decoder ADC, a sense amplifier SA, a booster circuit BS, and a transfer transistor portion WTB. The address decoder ADC is electrically connected to the transfer transistor portion WTB via the booster circuit BS. The resistor R is included as a circuit element not shown in the figure in the peripheral circuit PC.

The address decoder ADC is configured to select one block, which corresponds to an address signal provided from outside the device. When the drive voltage V_{RDEC} is provided from outside of the address decoder ADC and the block-selection signal is provided, the booster circuit BS boosts the drive voltage V_{RDEC} and supplies a prescribed voltage to each of the transfer-gate transistors WTGD, WTGS, and WT₀-WTₘ₋₁ via the transfer gate line TG.

The transfer transistor portion WTB has a transfer-gate transistor WTGD provided that corresponds to the selection-gate transistor STD on the bit-line side, a transfer-gate transistor WTGS provided that corresponds to the source-side selection-gate transistor STS, and the word-line transfer-gate transistors WT₀-WTₘ₋₁ provided that correspond to the memory cell transistors MT₀-MTₘ₋₁. A separate transfer-transistor portion WTB is provided for each block.

The transfer-gate transistor WTGD has either the drain or the source thereof connected to the selection-gate driver line SG2, and the other one of the source and drain is connected to the selection-gate line SGLD1. In this case, because the selection-gate line SGLD1 is connected to the drain side of each cell unit UC, it is referred to as the drain-side selection-gate line SGLD1. The transfer-gate transistor WTGS has either the drain or the source connected to the selection gate-driver line SG1, and the other one of the source or drain is connected to the selection-gate line SGLS1. In this case, because the selection-gate line SGLS1 is connected to the source-line side of each cell unit UC, it is referred to as the source-side selection-gate line SGLS1.

Among the transfer-gate transistors WT₀-WTₘ₋₁, either the drain or the source is connected to one of the word-line drive-signal lines WDL₀-WDLₘ₋₁, while the other one of the source or drain is connected to one of the word lines WL₀-WLₘ₋₁ provided inside the memory cell array Ar (memory region M).

For the bit line-side selection-gate transistors STD of the multiple cell units UC arranged in the row direction, the gate electrodes SG are electrically connected by the selection-gate line SGLD1. For the source-side selection-gate transistors STS of the multiple cell units UC arranged in the row direction, the gate electrodes SG are electrically connected by the source-side selection-gate line SGLS1. The sources of the source-side selection-gate transistors STS are commonly connected to the source line SL.

The selection-gate line SGLD2 connecting to the adjacent block (not shown in, but to the right, in the figure) and the bit line-side selection-gate transistor STD2 connected thereto share the connection CB between the source/drain region of the bit line-side selection-gate transistor STD1 connected to selection-gate line SGLD1 and the bit line and are arranged symmetrically with respect to the connection CB.

The source-side selection-gate line SGLS2 connected to the adjacent block not shown in the figure and the source-side selection-gate transistor STS2 connected thereto share the source-side selection-gate line SGLS1, the source/drain region of the source-side selection-gate transistor STS1 connected thereto, and the source line SL and are arranged symmetrically with respect to the position of the source-side selection-gate line SGLS1 and the source/drain region of the source-side selection-gate transistor STS1 with respect to the source line SL.

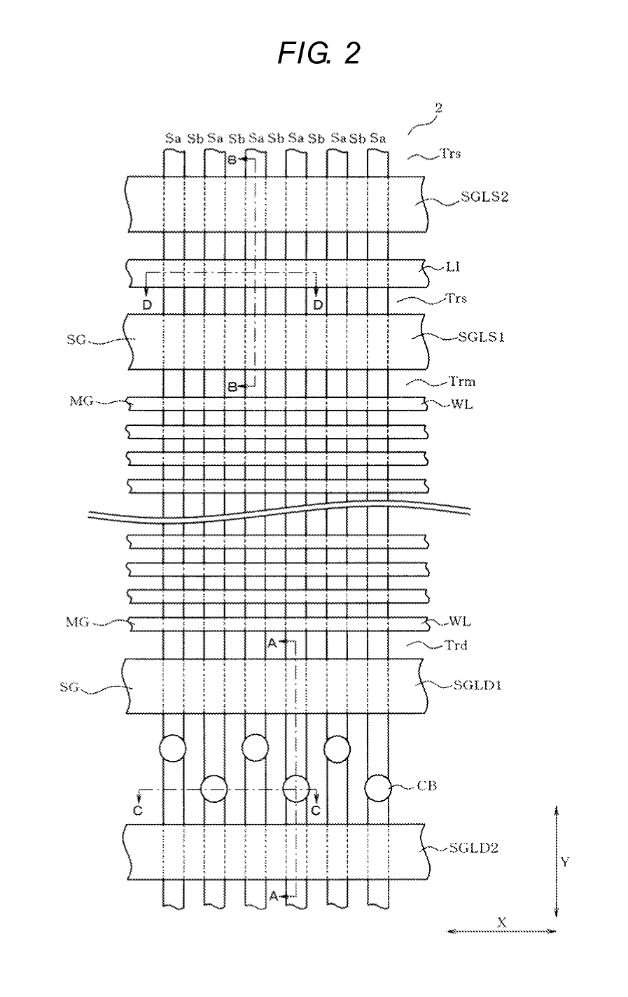

The gate electrodes of the memory cell transistors MT₀-MTₘ₋₁ of the plurality of the cell units UC arranged in the row direction are electrically connected using the word lines WL₀-WLₘ₋₁, respectively. The memory cell transistors MT₀-MTₘ₋₁ are referred to as the memory cell transistor Trm in the explanation of FIG. 2.

The gate electrodes of the transfer-gate transistors WTGD, WTGS, and WT₀-WTₘ₋₁ are commonly connected to each other via the transfer-gate line TG. These gate electrodes are thus connected to the boosted voltage supply terminal of the booster circuit BS. The sense amplifier SA is connected to the bit lines BL₀-BLₙ₋₁ (connection not shown in the Figure), and a latch circuit (not shown) is connected to temporarily store the data during the reading of these data. In FIG. 2 and thereafter, various transistors formed in the peripheral circuit region are referred to as TrP and are used in the explanation.

FIG. 2 is the plan view of the layout pattern in a portion of the memory cell region. As shown in FIG. 2, in the memory cell region on the semiconductor substrate 2, an isolation structure region Sb having an STI (shallow trench isolation) structure formed by burying an insulating film in a trench formed in the semiconductor substrate 2 is formed to extend along direction Y in FIG. 2. The multiple isolation structure regions Sb are formed at a prescribed interval or spacing in direction X in FIG. 2. Active regions Sa are formed to extend along direction Y in FIG. 2, between adjacent, or to the side of, an isolation region Sb. The multiple active regions Sa are formed spaced from each other in direction X in the surface layer of the semiconductor substrate 2, with isolation regions Sb extending therebetween.

The word line WL is formed to extend in the direction perpendicular to the active regions Sa (direction X in FIG. 2). The multiple word lines WL are formed at a prescribed interval in direction Y in FIG. 2. The memory cell transistor Trm is formed having the gate electrode MG in the active region Sa at the place where the word line WL and the active region Sa cross each other. The gate electrode MG can also be a portion of the word line WL. The multiple memory cell transistors Trm that are adjacent to each other in direction Y become part of the NAND string (memory cell string).

The selection-gate transistors Trs and Trd are provided adjacent to the two outer sides of the memory cell transistors Trm at the two ends of the NAND string in direction Y. The multiple selection-gate transistors Trs and Trd are provided in direction X. The gate electrodes SG of the multiple selection-gate transistors Trs and Trd are electrically connected through the drain-side gate line SGLD1 and the source-side selection-gate line SGLS1. The selection-gate transistor Trd is formed having the gate electrode SG as the drain-side selection-gate line SGLD1, in the active region Sa at the place where the drain-side selection-gate SGLD1 and the element region Sa cross each other. The bit-line contact CB is formed, and extends upwardly (from the surface of FIG. 2) on the active region Sa between the adjacent drain-side selection-gate lines SGLD1 and SGLD2. The opening into which the bit-line contact CB is formed is appropriately sized and positioned so that bit line contacts CB are individually connected on each element region Sa.

The selection gate transistor Trs is formed in the element region Sa at the gate electrode SG that forms the source-side selection-gate line SGLS1 at the place where the source-side selection-gate SGLS1 crosses the element region Sa. The source-line contact LI is formed such that the multiple element regions Sa are commonly connected on the element region Sa between the adjacent pair of the source-side selection-gate lines SGLS1 and SGLS2. In FIG. 2, the source-line contact is shown as a narrow line in a trench extending in direction X.

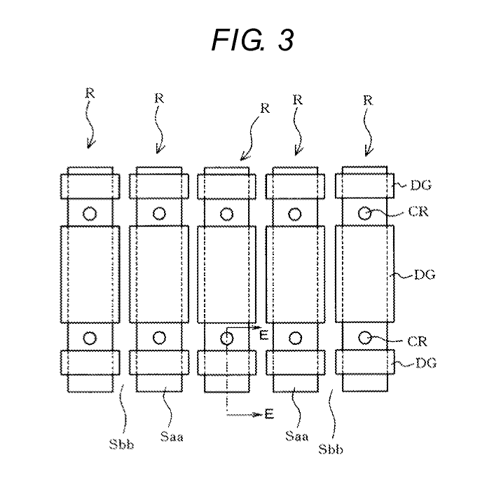

FIG. 3 is a plan view illustrating resistors R as an example of an element formed in the peripheral circuit region. This figure shows the state in which the resistors R are arranged side by side. The resistor R is formed in a rectangular active region Saa isolated by an element-isolation region Sbb which extends on or into the substrate on which the resistors R are formed. A conductor layer acting as the resistive element of the resistor R is formed on the active region Saa. A pair of contacts CR for the resistor are formed on, and extend upwardly from, the two ends of the conductor layer of the active region Saa. During the formation of the gates of the memory cell transistor, a gate is formed as a dummy gate DG on the top surface of the conductor layer, except in the area thereof where the contact CR is to be formed. The conductor layer extending between each pair of contacts CR functions as the resistor R. The number of resistors R and the connection method are not limited to those shown in the figure. By setting the number and the distance between the contacts CR appropriately, the resistors can be connected appropriately to realize a prescribed resistance value. The contact CR for resistor is formed in an opening in an insulating film layer overlying the conductor layer that is opened individually, i.e., in a separate process step or series of steps during the formation of the memory device.

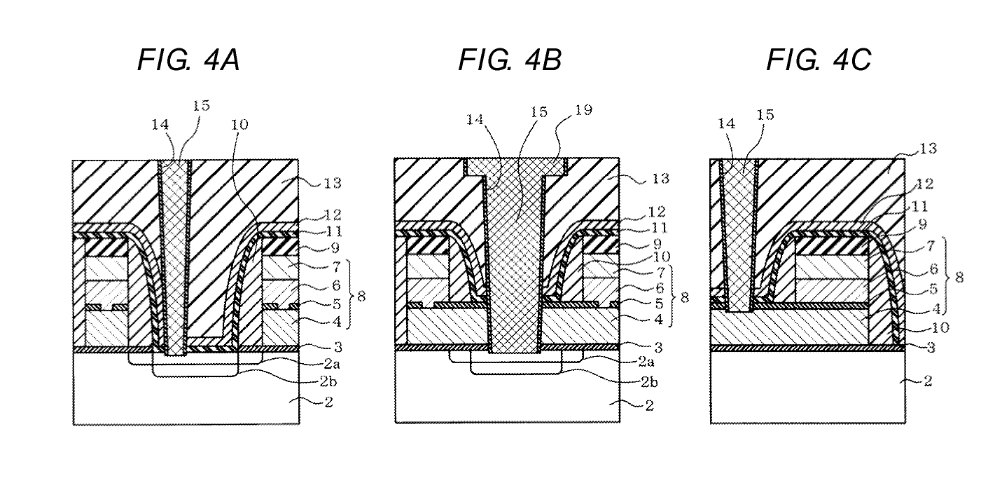

FIGS. 4A to 8C are longitudinal cross-sectional views that schematically illustrate the configuration of the.

In FIGS. 4A to 8C, the A FIG. s show the cross-sectional view of the contact CB extending to the bit line located between the selection-gate lines on the drain side, that is, the cross-sectional view along line A-A in FIG. 2, the B FIG. s show the source-line LI contact between the selection gates on the source side, that is, the cross-sectional view along line B-B in FIG. 2, and the C FIG. s show a cross-sectional view along line E-E of the resistor R shown in FIG. 3.

First, FIGS. 4A to 4C will be explained. FIGS. 4A to 4C are cross-sectional views illustrating the state when a series of steps described in the embodiment to form the memory device have been completed.

FIG. 4A is a cross-sectional view along line A-A in FIG. 2 illustrating the contact CB connecting to the bit line between the selection-gate lines (SGLD1 and SLGD2 on the drain side. A first polysilicon film 4, a polysilicon inter-film-insulating film 5, a second polysilicon film 6, and tungsten (W) as the metal film 7 are sequentially formed on the gate-insulating film 3 onto the semiconductor substrate 2 to form the gate electrodes 8. The first insulating film 9 is formed thereover.

The first polysilicon film 4, the polysilicon inter-film-insulating film 5, and the second polysilicon film 6 are also formed in the gate electrode of the transistor used in the memory cell region. These films are formed in the same steps in which the selection gate transistor gates are formed. A silicon oxide film formed using the thermal oxidation method or a silicon oxynitride film (SiON) formed by performing a plasma nitridation treatment on a silicon oxide film can be used as the gate-insulating film 3. In this embodiment, the polysilicon inter-film-insulating film 5 has an opening therein to allow the first polysilicon film 4 and the second polysilicon film 6 to be electrically connected to each other.

A sidewall-insulating film 10 is provided on the sidewall surface of the gate electrode 8 and the first insulating film 9. The sidewall-insulating film is covered by a second insulating film 11 and a liner-insulating film 12. In this embodiment, a silicon oxide film is used as the first insulating film 9, the sidewall-insulating film 10, and the second insulating film 11, while a silicon nitride film is used as the liner-insulating film 12.

An interlayer-insulating film 13 is formed over the top surface of the liner-insulating film 12. A contact, i.e., a conductive film 15 is formed opening penetrating through the interlayer-insulating film 13, the liner-insulating film 12, and the second insulating film 11. The contact film 15 extends to, and is physically in contact with the surface of the semiconductor substrate 2. The sidewall of the opening in which the contact film 15 is formed is covered or lined by a third insulating film 14. In this embodiment, a silicon oxide film is used as the interlayer-insulating film 13 and the third insulating film 14. The contact film 15 buried in the contact is formed of a barrier metal (not shown in the figure), which includes a film of titanium, titanium nitride, and tungsten (W), with the titanium and titanium nitride lining the sidewalls of the opening, and the tungsten providing the bulk of the contact. Also, a first impurity region 2a and a second impurity region 2b are formed on the semiconductor substrate 2. For example, phosphorous (P) is doped in the first impurity region 2a, and arsenic (As) is doped in the second impurity region 2b.

FIG. 4B is the cross-sectional view along line B-B in FIG. 2 illustrating the source-line contact LI formed between the source-side selection-gate lines. The first polysilicon film 4, the polysilicon inter-film-insulating film 5, the second polysilicon film 6, and tungsten (W) as the metal film 7 are sequentially formed over the gate-insulating film 3 on the semiconductor substrate 2. The first polysilicon film 4 and the polysilicon inter-film-insulating film 5 extend inwardly of the opening from the opening side of the second polysilicon film 6 and together form the gate electrode 8. The first insulating film 9 is formed on the top of the gate electrode 8.

The contact film 15 is formed by being deposited in the contact opening which penetrates through the interlayer-insulating film 13, the liner-insulating film 12, the second insulating film 11, the polysilicon inter-film-insulating film 5, the first polysilicon film 4, and the gate-insulating film 3. The contact film 15 contacts the surface of the semiconductor substrate 2. The sidewall of the contact opening in which the contact-conductive film 15 is formed is covered (lined) by the third insulating film 14. In this way, the first polysilicon film 4 and the contact film 15 are insulated from one another to prevent an electric short circuit. Also, as shown in the figure, the first polysilicon film 4 is electrically cut off in the horizontal direction in FIG. 4B by the penetration of the contact opening therethrough. In this embodiment, a silicon oxide film is used as the interlayer-insulating film 13 and the third insulating film 14. The contact film 15 in the contact includes a barrier metal (not shown in the figure), which includes a film stack of titanium and titanium nitride, over which a bulk tungsten (W) plug is located.

FIG. 4C is the cross-sectional view along line E-E of the resistor R shown in FIG. 3. The resistor R is a typical example of the element having a structure in which a contact opening extends into the first polysilicon film, and a contact is connected to the first polysilicon film 4 that as will be described later herein. This design structure is not limited to the resistor R of FIG. 4C, but can be applied to any element or part of an element as long as the element has a structure having an opening extending into or at least to the first polysilicon film 4. The first polysilicon film 4, the polysilicon inter-film-insulating film 5, the second polysilicon film 6, and tungsten (W) as the metal film 7 are sequentially provided on the gate-insulating film 3 located on the semiconductor substrate 2. The first polysilicon film 4 and the polysilicon inter-film-insulating film 5 extend from at least one side surface of the second polysilicon film 6 and together form the gate electrode 8. Then, the first insulating film 9 is formed thereon.

The first polysilicon film 4, the polysilicon inter-film-insulating film 5, and the second polysilicon film 6 have the same film configuration as the gate electrode of the transistor used in the memory cell region. The first polysilicon film 4 is formed in the same step as the floating gate of the gate electrode of the transistor in the memory cell. The second polysilicon film 6 is formed in the same step as the control gate of the memory cell transistor. The sidewall-insulating film 10 is formed to cover the sidewall of the gate electrode 8 and the first insulating film 9. The entire surface of the sidewall-insulating film is covered by the second insulating film 11 and the liner-insulating film 12. In this embodiment, a silicon oxide film is used as the first insulating film 9, the sidewall-insulating film 10, and the second insulating film 11, and a silicon nitride film is used as the liner-insulating film 12. The interlayer-insulating film 13 is formed thereover. The contact-conductive film 15 is formed by being deposited in the contact opening which is formed to penetrate through the interlayer-insulating film 13, the liner-insulating film 12, the second insulating film 11, and the polysilicon inter-film-insulating film 5. The contact conductive film 15 thus contacts the surface of the first polysilicon film 4. The sidewall of the contact-opening portion in which the contact-conductive film 15 is formed is covered by the third insulating film 14. In this embodiment, a silicon oxide film is used as the interlayer-insulating film 13 and the third insulating film 14. The contact-conductive film 15 deposited in the contact includes a barrier metal (not shown in the figure), which includes a laminated film of titanium and titanium nitride, and a tungsten (W) bulk film fills the opening over the titanium and titanium nitride films.

In the following, the sizes of the bit-line contact CB, the contact CR for the resistor, and the source-line contact LI that have been explained based on FIGS. 4A-4C will be described. The bit-line contact CB and the contact CR for the resistor have individual contact openings. On the other hand, the source-line contact LI is formed across multiple active regions and multiple element-isolation regions to commonly connect to the multiple adjacent active regions. Therefore, the source-line contact LI has a larger opening with a larger cross sectional area than the bit-line contact CB or the contact CR for the resistor. Consequently, the contact opening of the source-line contact LI has a lower aspect ratio (depth over width) compared with the bit-line contact CB and the contact CR for the resistor.

In the following, each fabrication step of the embodiment will be described sequentially based on FIGS.-8.

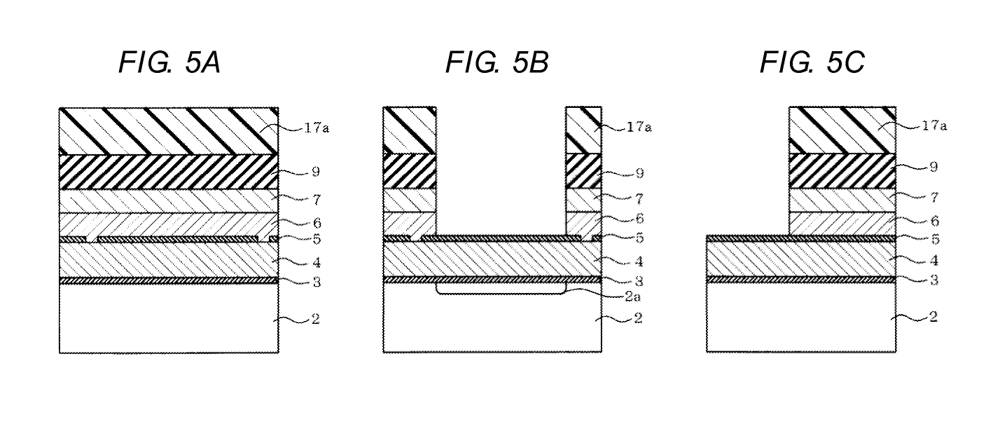

First, as shown in FIG. 5, the gate-insulating film 3, the first polysilicon film 4, and the polysilicon inter-film-insulating film 5 are formed sequentially on the semiconductor substrate 2. After that, a photoresist layer is formed by a lithography step (not shown in the figure) is used as a mask to etch the polysilicon inter-film-insulating film 5. When part of the polysilicon inter-film-insulating film 5 is removed selectively, and opening is formed therein which enables electrical conduction between the first polysilicon film 4 and the second polysilicon film 6 to be formed in a later step. Then, the second polysilicon film 6 is formed. After that, a tungsten (W) metal film 7 is deposited, followed by forming the first insulating film 9 thereon. The first polysilicon film 4 is equivalent to, and forms, the floating-gate electrode of the memory cell-gate electrode (not shown in the figure). The second polysilicon film 6 is equivalent to, and forms, the control gate of the memory cell-gate electrode (not shown in the figure). The polysilicon inter-film-insulating film 5 is equivalent to, and forms, the insulating film formed between the floating gate and the control gate of the memory cell-gate electrode (not shown in the figure). These films are formed in sequential steps in this embodiment. For example, an ONO film (oxide-nitride-oxide film) formed by layering a silicon oxide film/silicon nitride film/silicon oxide film, a NONON film (nitride-oxide-nitride-oxide-nitride film), or an insulating film with a high dielectric constant can be used as the polysilicon inter-film-insulating film 5. The tungsten film can be formed using a sputtering method or a CVD method (chemical vapor deposition).

Then, a patterned photoresist layer 17a is formed thereover by means of lithography. This photoresist layer is used as a mask to carry out patterned etching to form the gate electrode. In the source-line contact LI portion between the selection gates on the source side shown in FIG. 5B and the contact CR portion for the resistor R shown in FIG. 5C, the pattern of the photoresist layer 17a is formed and used as a mask to remove the first insulating film 9, the metal film 7, and the second polysilicon film 6 by means of etching. The etching operation is stopped on the polysilicon inter-film-insulating film 5. Consequently, the polysilicon inter-film-insulating film 5 and the first polysilicon film 4 are left in place without being etched. In other words, in this embodiment, the gate electrodes in the source-line contact LI portion between the selection gates on the source side shown in FIG. 5B and the contact CR part for the resistor R shown in FIG. 5C are etched in the same step. On the other hand, in the contact CB part to the bit line between the selection-gate lines on the drain side shown in FIG. 5A, the entire surface is covered by the photoresist layer 17a and hence is not etched. Then, ions are implanted selectively into the source-line contact LI part between the selection gates on the source side shown in FIG. 5B, and thus impurities in the form of dopants are implanted into the semiconductor substrate 2. The impurities are implanted using an ion-implantation method into the semiconductor substrate 2. For example, phosphorous (P) ions are implanted with an implant energy of 200 keV at a dosage of 1×10¹⁴ atms/cm² into the semiconductor substrate after penetrating through the polysilicon inter-film-insulating film 5, the first polysilicon film 4, and the gate-insulating film 3.

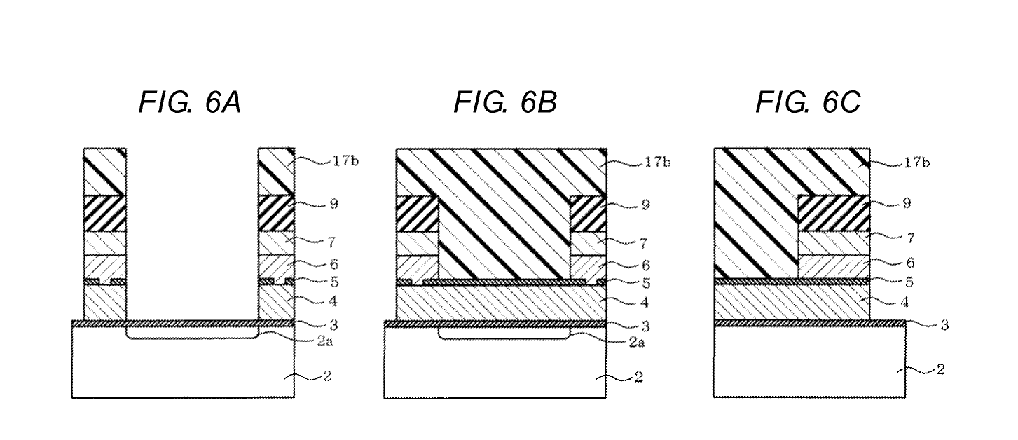

Then, as shown in FIG. 6, a patterned photoresist layer 17b is formed in the next lithographic step. This photoresist layer is used as a mask to carry out the second etching used for forming the gate electrode. The pattern of the photoresist layer 17b is etched into the contact CB portion of the bit line between the selection-gate lines on the drain side shown in FIG. 6A, at the left end shown in FIG. 6B and the right end shown in FIG. 6C. This photoresist layer 17b is used as a mask to sequentially etch the first insulating film 9, the metal film 7, the second polysilicon film 6, the polysilicon inter-film-insulating film 5, and the first polysilicon film 4. The etching is stopped on the gate-insulating film 3. On the other hand, because the source-line contact LI portion between the selection gates on the source side shown in FIG. 6B and the contact CR part for the resistor R shown in FIG. 6C are covered by the pattern formed by the photoresist layer 17b, the polysilicon inter-film-insulating film 5 and the first polysilicon film 4 left in the step shown in FIG. 5 are not etched. As a result of this step, the gate electrode 8 and the first insulating film 9 are formed thereon. After that, ions are implanted selectively into the contact CB portion adjacent to the bit line between the selection-gate lines on the drain side shown in FIG. 6A to form the first impurity (doped)region 2a in the semiconductor substrate 2. To inject the impurity, for example, phosphorous ions (P) are implanted with an implant energy of 40 keV at a dosage of 1×10¹⁴ atms/cm² into the semiconductor substrate 2.

In this case, the step shown in FIG. 6 is carried out after the step shown in FIG. 5. However, it is also possible to switch the order of these steps. In other words, it is also possible to carry out the step shown in FIG. 5 after carrying out the step shown in FIG. 6.

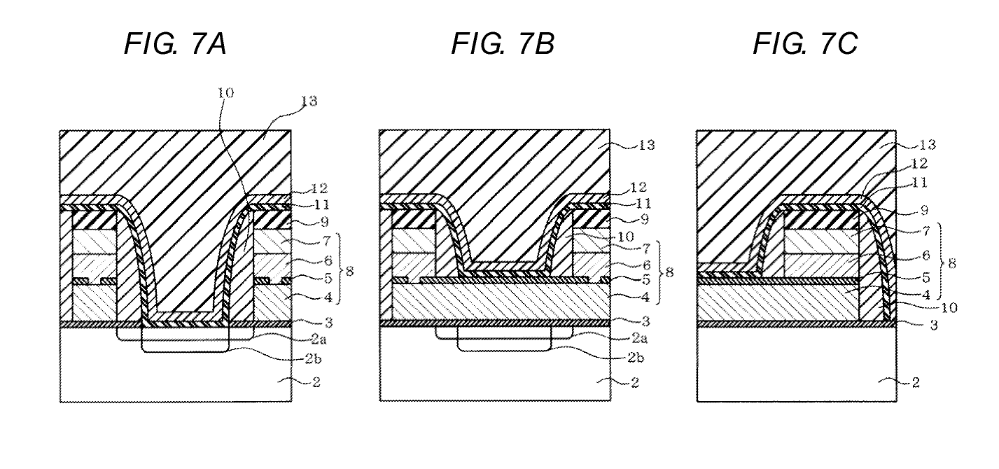

Then, as shown in FIG. 7, after the photoresist layer 17b is removed, an insulating film is formed over the entire substrate. After that, an etchback is carried out by means of anisotropic dry etching on the entire surface to form the sidewall-insulating film 10 on the side surface of the gate electrode and the first insulating film 9. In this case, the sidewall-insulating film 10 is formed of a silicon oxide film. As a result of this etchback step, the top surface and the side surface in direction X of the gate electrode 8 are covered by the first insulating film 9 on the gate electrode 8 and the sidewall-insulating film 10. As shown in FIG. 7A, because the gate-insulating film on the semiconductor substrate 2 not covered by gate electrode 8 and sidewall-insulating film 10 is etched, the surface of the semiconductor substrate 2 is exposed in that area. As shown in FIGS. 7B and 7C, in the region where the polysilicon inter-film-insulating film 5 and the second polysilicon film 6 remain, the sidewall-insulating film 10 is formed on the polysilicon inter-film-insulating film 5. The polysilicon inter-film-insulating film 5 is left in the region not covered by the gate electrode 8 and the sidewall-insulating film 10.

Then, using the photoresist pattern (not shown in the figure), the gate electrode 8, the first insulating film 9, and the sidewall-insulating film 10 as a mask, impurities are implanted into the opened region shown in FIG. 7A. To implant the impurity (dopant), for example, arsenic (As) ions are implanted using the ion-implant method with an implant energy of 50 keV at a dosage of 1×10¹⁵ atms/cm². Also, using the photoresist pattern (not shown in the figure), the gate electrode 8, and the sidewall-insulating film 10 as a mask, impurity is implanted into the substrate in the opened region shown in FIG. 7B. To implant the impurity (dopant ions or atoms), for example, arsenic (As) ions are implanted using the ion-implant method with an injection energy of 250 keV at a dosage of 1×10¹⁵ atms/cm² into the semiconductor substrate after penetrating through the polysilicon inter-film insulating film 5, the first polysilicon film 4, and the gate-insulating film 3. As a result of this step, the second impurity region 2b is formed in the semiconductor substrate 2 in the region shown in FIGS. 7A and 7B. No impurity is injected into the region shown in FIG. 7C because it is covered (masked) by a photoresist layer (not shown in the figure) during the ion implant step. Therefore, no impurity region is formed in that area of the substrate. Then, the second insulating film 11, the liner-insulating film 12, and the interlayer-insulating film 13 are formed over the entire surface of the substrate.

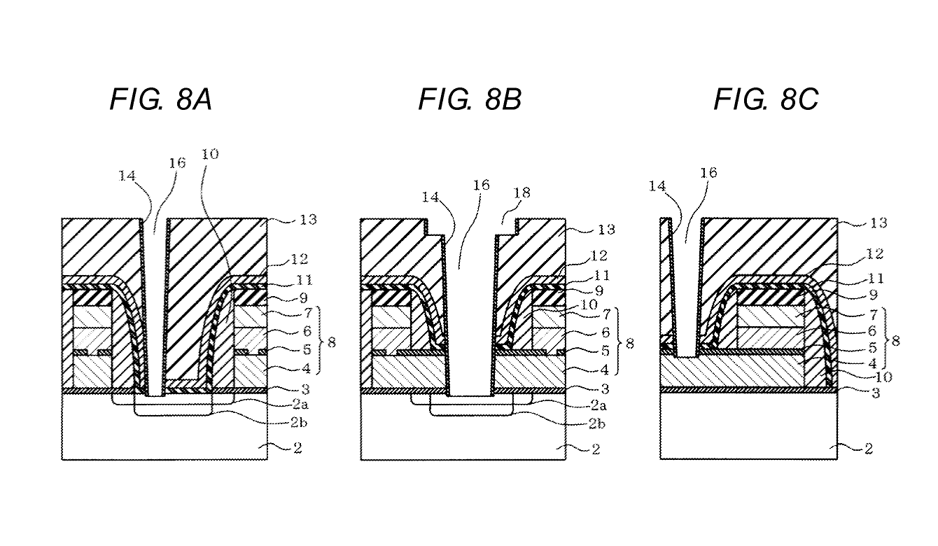

Then, as shown in FIG. 8, with a photoresist layer (not shown in the figure) used as a mask, etching is carried out to form the contact openings 16 extending inwardly of the interlayer insulating film 13. The openings 16 for contact CB to the bit line located between the selection-gate lines on the drain side shown in FIG. 8A and the contact CR for the resistor shown in FIG. 8C have a small opening area. On the other hand, the contact opening extending to source-line LI between the selection gates on the source side shown in FIG. 8B is an opening with a large opening area that is opened as a trench.

Even when the etching of the contact features of FIGS. 8A to 8C is carried out under the same conditions and in the same etch step, the pattern feature with the larger opening will have a higher etching rate, while the pattern with the smaller opening section will have a lower etching rate. In other words, the etching rate is higher and the amount of etching is larger for a pattern feature with a larger opening section. Consequently, because the contact opening to the source-line LI portion as is shown in FIG. 8B has a larger opening area than the openings for the contact CB shown in FIG. 8A and the contact CR for the resistor shown in FIG. 8C, the etching is carried out more quickly in the opening of FIG. 8B, and the contact hole in the contact opening in FIG. 8B reaches the polysilicon inter-film-insulating film 5 and the first polysilicon film 4 faster than it reaches the semiconductor substrate 2. Thereafter, the contact opening 16 in FIG. 8B continues to be etched through down to the semiconductor substrate 2. During the over-etching period for the uniformity of the overall amount of etching, in the contact opening of the source-line contact LI part, the contact opening penetrates completely through the polysilicon inter-film-insulating film 5 and the first polysilicon film 4 and also penetrates through the gate-insulating film 3 to reach the surface of the semiconductor substrate 2, and then etching is stopped. Because the contact CR for the resistor shown in FIG. 8C is a mach smaller in cross section, the opening 16 therefore has a small cross sectional area and a lower etching rate, the etching progress therein is slower compared with the etching rate of the opening 16 for the source-line contact LI part shown in FIG. 8B. Therefore, because the etching ends in the state when the etching has stopped on the first polysilicon film 4, the contact opening does not penetrate through the first polysilicon film 4 to reach the semiconductor substrate 2.

As described above, openings 16 can be formed for the contact CB as shown in FIG. 8A, for the source-line as LI shown in FIG. 8B, and the contact CR for the resistor as shown in FIG. 8C in the same etch step. Etching or eroding of the semiconductor substrate 2 at the base of the source-line contact LI opening shown in FIG. 8B is restrained, etching stops on the first polysilicon film 4 in the contact CR opening for the resistor shown in FIG. 8C, and the contact opening 16 for contact CB which extends to the semiconductor substrate 2 can be formed as shown in FIG. 8A. In other words, it is possible to take advantage of the difference in the etching rates caused by the differences in the opening areas to make adjustments such that the etching ending times of the openings for the different contacts having different opening areas can be almost the same.

Thereafter, a facet 18 is formed the interlayer insulating film 13 at the opening 16 therein for the contact for the source line LI in which the conductive contact film and wiring, using the dual damascene method step in the region shown in FIG. 8B, will be formed in a later process step. After the facet is formed, the third insulating film 14 is formed on the sidewall of the groove patterns 16 and the facet 18 as shown in FIGS. 8A, 8B and 8C. The third insulating film 14 is, for example, a silicon oxide film.

Then, as shown in FIG. 4, a barrier metal is formed in the facet 18 and the contact opening 16 of FIGS. 8A, 8B and 8C over the third insulating film 14. Thereafter, tungsten is deposited to fill the opening. Any barrier metal and tungsten formed on the interlayer-insulating film 13 during the opening fill process is removed by means of CMP (chemical mechanical polishing) to result in the conductive contact 15 and the wiring 19 in the contact trench of FIG. 8B. In this case, a film of titanium (Ti) and titanium nitride (TiN) used as the barrier metal can be formed using the sputtering method or the CVD method. The tungsten film can be formed using the CVD method. The structure used herein is known as the via first dual damascene structure because the conductive contact film 15 and the wiring 19 are formed openings in a dielectric layer after the openings 16 are formed, followed by depositing the conductive contact material and removing the unnecessary portion of the conductive film overlying the dielectric (insulative film layer) by means of CMP.

The semiconductor device of this embodiment is formed as described above.

According to this embodiment, as shown in FIG. 5, in the step for forming the gate electrode, because the source-line contact LI part between the selection gates on the source side shown in FIG. 5B and the contact CR part for the resistor R shown in FIG. 5C can be carried out in the same step, there is no need to add additional resist coating, exposing a developing steps to form the contact openings in different steps. The number of steps can be effectively reduced.

According to this embodiment, as shown in FIG. 8, because the contact CB to the bit line between the selection-gate lines on the drain side shown in FIG. 8A, the source-line contact LI between the selection gates on the source side shown in FIG. 8B, and the contact CR for the resistor shown in FIG. 8C can be processed in the same step, there is no need to process these contact openings in different steps. The number of steps can be effectively reduced.

As shown in FIG. 8B, the first polysilicon film 4 is formed in the opening region of the source-line contact LI part between the selection gates on the source side and it is penetrated during the etching of the opening. This film must be etched through before the opening can reach the underlying silicon, and thus, it is possible to restrain erosion of the semiconductor substrate 2 on the bottom surface of the contact opening compared with the case when the first polysilicon film 4 is not so formed and penetrated during etch.

To realize this step, in this embodiment, as shown in FIG. 4B, in the source-line contact LI part to the bit line between the selection-gate lines on the source side, the first polysilicon film 4 and the polysilicon inter-film-insulating film 5 extend inwardly of the inner walls of the second polysilicon film into which an opening is etched using the photoresist layer 17a to remove the first insulating film 9, the metal film 7, and the second polysilicon film 6 but stop on the inter film insulating layer 5 as is shown in FIG. 5B. The conductive contact film 15 of the source-line contact LI is formed in the contact-opening portion formed to extend through the interlayer-insulating film 13, the liner-insulating film 12, the second insulating film 11, the polysilicon inter-film-insulating film 5, the first polysilicon film 4, and the gate-insulating film 3, and the contact-conductive film 15 is connected to the surface of the semiconductor substrate 2. Also, when the sidewall of the contact-opening portion in which the conductive contact film 15 is formed is covered by the third insulating film 14, the first polysilicon film 4 and the contact-conductive film 15 can be insulated from each other to prevent a short circuit, and the first polysilicon film 4 is cut off into the left and right sections as shown in the figure by the source-line contact LI part.

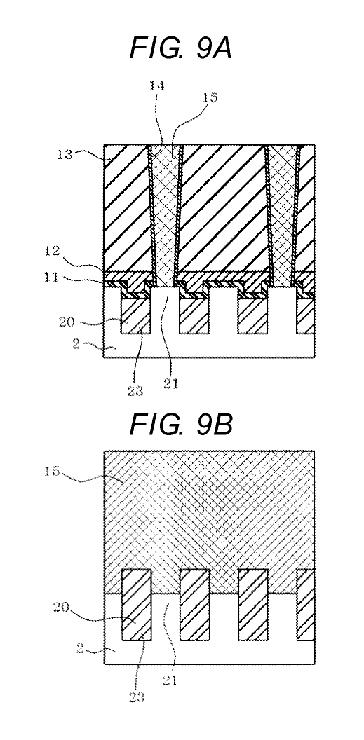

In the following, each step in the fabrication process in this embodiment will be described sequentially based on FIGS. 9-13.

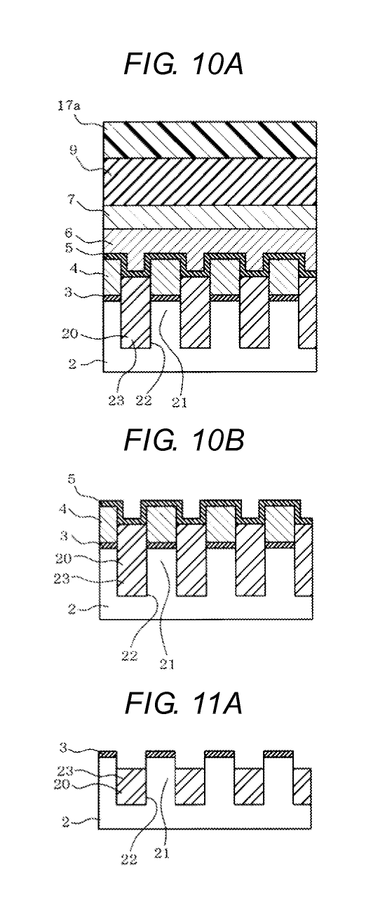

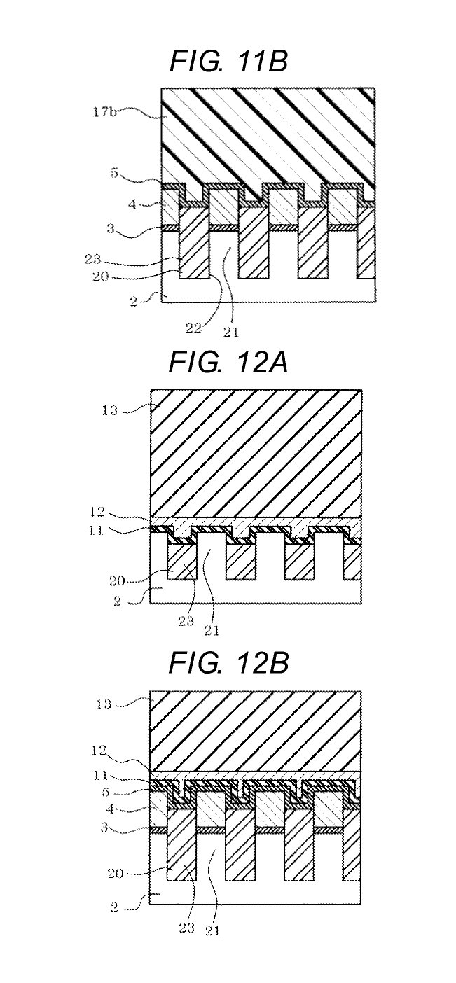

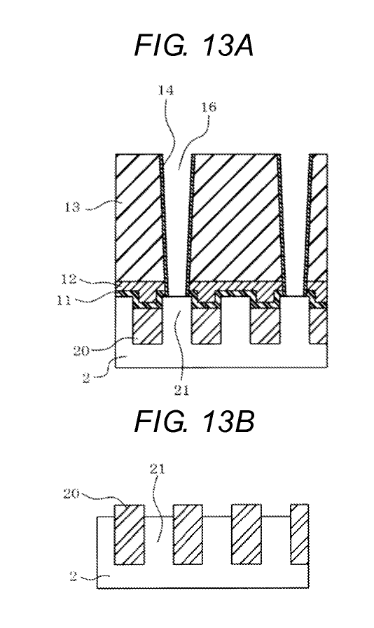

FIGS. 9-13 are longitudinal cross-sectional views schematically illustrating the configuration to which the embodiment is applied in the order of the steps for explaining the embodiment. For FIGS. 9A to 13B, A is the cross-sectional view of the contact CB to the bit line between the selection-gate lines on the drain side along line C-C in FIG. 2, and B is the cross-sectional view of the source-line contact LI part between the selection gates on the source side along line D-D in FIG. 2. The steps shown in FIGS. 4 and 9 are the same steps and are the steps shown in FIGS. 5 and 10, the steps shown are in FIGS. 6A to 6C and 11A and 11B, the same steps are shown in FIGS. 7A to 7C and 12A and 12B, and the same steps are shown in FIGS. 8 and 13. The cross-section is different between these pairs of figures. For example, the element-isolation region 20 is not shown in FIGS. 4, 5, 6, 7, and 8, but it is shown in FIGS. 9, 10, 11, 12, and 13.

The steps are the same as those that have been described above based on FIGS. 4A to 8C. The constituent elements of the same symbols are the same parts, and the specific materials are the same that have been described in FIGS. 4A to 8C.

First, FIG. 9 will be explained. FIGS. 9A and 9B show a cross-sectional view illustrating the state when a series of steps disclosed in the embodiment have been completed.

FIG. 9A is the cross-sectional view of the contact CB part to the bit line between the selection-gate lines on the drain side along line C-C in FIG. 2. The figure shows the semiconductor substrate 2, the gate-insulating film 3 formed on the semiconductor substrate 2, the element-isolation regions 20 with an STI structure formed by forming an insulating film in the trenches formed in the semiconductor substrate 2, and the active regions 21 divided by the element-isolation regions 20. The second insulating film 11, the liner-insulating film 12, and the interlayer-insulating film 13 are formed above the element-isolation region 20. The contact-conductive film 15 is formed in the contact opening portion in the active region 21 to penetrate through the interlayer-insulating film 13, the liner-insulating film 12, and the second insulating film 11. The conductive contact film 15 is connected to the active region 21.

FIG. 9B is the cross-sectional view of the source-line contact LI to the bit line between the selection-gate lines on the source side along line D-D in FIG. 2. The figure shows the semiconductor substrate 2, the element-isolation region 20 with STI structures formed by depositing an insulating film in the trenches formed on the semiconductor substrate 2, and the active regions 21 separated by the element-isolation regions 20. The conductive contact film 15 is deposited over and in the contact opening formed in the element-isolation region 20 and the active region 21 to extend through the interlayer-insulating film 13, the liner-insulating film 12, the second insulating film 11, the polysilicon inter-film-insulating film 5, the first polysilicon film 4, and the gate-insulating film 3 not shown in this cross-sectional view. The conductive contact film is commonly connected to multiple active regions 21.

In the following, the fabrication process of the embodiment will be described in the order of the steps based on FIGS. 9A to 13B.

First, FIGS. 10A and 10B will be explained. The step shown in FIG. 10 is the same as that shown in FIGS. 5A to 5C, but showing processing of a different feature or region on the substrate 2. First, the gate-insulating film 3 and the first polysilicon film 4 are formed on the semiconductor substrate 2. After that, the first polysilicon film 4 and the gate-insulating film 3 are selectively removed by pattern etching, and the semiconductor substrate 2 is etched in a lithographic step (not shown in the figure) to form the trench in the semiconductor substrate 2. Then, the element isolation-insulating film 23 is deposited in the trench 22, thereby forming the element-isolation region 20 of an STI structure. The active region 21 is divided by the element-isolation region 20. The active region 21 is used as the channel region or the source/drain region of the transistor after undergoing the subsequent steps. Then, the polysilicon inter-film-insulating film 5, the second polysilicon film 6, and the metal film 7 are formed, and the first insulating film 9 is formed thereon.

Then, the photoresist layer 17a is formed and patterned by means of lithography. The photoresist layer is used as a patterned mask to carry out the etching for forming the gate electrode. In the source-line contact LI part between the selection gates on the source side shown in FIG. 10B, the photoresist layer 17a is selectively patterned. There is no photoresist layer on the cross section in the region shown in the figure. In this region, the first insulating film 9, the metal film 7, and the second polysilicon film 6 which are not covered by photoresist are removed by means of etching, and the etching stops on the polysilicon inter-film-insulating film 5. The polysilicon inter-film-insulating film 5 and the first polysilicon film 4 are left without being etched. On the other hand, where the contact CB opening to the bit line between the selection-gate lines on the drain side shown in FIG. 10A is formed, the entire surface is covered by the photoresist layer 17a, and no etching is performed in that region in this step.

Then, as shown in FIGS. 11A and 11B, after the photoresist layer 17a is removed, the photoresist layer 17b is formed and patterned the next lithographic step, and this photoresist layer is used as a mask to carry out etching. At the location of the contact CB to the bit line between the selection-gate lines on the drain side shown in FIG. 11A, the photoresist layer 17b is selectively patterned. There is no photoresist layer existing on the cross section in the region shown in the figure. In that region, the first insulating film 9, the metal film 7, the second polysilicon film 6, polysilicon inter-film-insulating film 5, and the first polysilicon film 4 are etched sequentially. In the active region 21, the etching is stopped on the element isolation-insulating film 23 in the element-isolation region 20 on the gate-insulating film 3. As a result of this etching step, the surface of the element isolation-insulating film 23 retreats (i.e., it is etched back) and becomes lower than the surface of the active region 21. On the other hand, in the source-line contact LI portion between the selection gates on the source side shown in FIG. 11B, the entire surface is covered by the photoresist layer 17b, and no etching thereof is performed in this step.

In this case, the step shown in FIGS. 11A and 11B is carried out after the step shown in FIGS. 10A and 10B. However, it is also possible to switch the order of these steps. In other words, it is also possible to carry out the step shown in FIGS. 10A and 10B after carrying out the step shown in FIGS. 11A and 11B.

Then, as shown in FIGS. 12A and 12B, the photoresist layer 17b is removed. After the sidewall-insulating film 10 is formed, the second insulating film 11, the liner-insulating film 12, and the interlayer-insulating film 13 are formed on the entire surface of the substrate.

Then, as shown in FIG. 13, a photoresist layer (not shown in the figure) is used as a mask to carry out the etching for forming the contact opening. The contact CB to the bit line between the selection-gate lines on the drain side shown in FIG. 13A is formed in an opening with a small opening area. On the other hand, for the opening for the source-line contact LI between the selection gates on the source side, FIG. 13B shows the cross section of the central part of the opening section that is narrow in the horizontal direction in the figure. The contact-opening portion in this source-line contact LI part has a larger opening area than the contact CB part. The entire surface is shown as the source-line contact LI in FIG. 13B.

As described above, even if the etching is carried out under the same conditions in the same step, the pattern with the larger opening section will have a higher etching rate, while the pattern with the smaller opening section will have a lower etching rate. By taking advantage of this fact, it is possible to make adjustments such that the etching ending time for the contact opening in the source-line contact LI and the contact CB becomes almost the same.

In the region shown in FIG. 13A, the contact opening 16 is formed to penetrate through the interlayer-insulating film 13, the liner-insulating film 12, and the second insulating film 11 to reach the surface of the active region 21 of the semiconductor substrate 2. In the region shown in FIG. 13B, the contact-opening portion 16 is formed to penetrate through the interlayer-insulating film 13, the liner-insulating film 12, the second insulating film 11, the polysilicon inter-film-insulating film 5, the first polysilicon film 4, and the gate-insulating film 3 to reach the semiconductor substrate 2. Because FIG. 13B shows the cross section in the central part along the extension direction of the contact-opening portion 16 that extends in the horizontal direction on the figure, this figure becomes a cross-sectional view illustrating the state when these films have been removed from the entire surface. Then, the third insulating film 14 is formed on the sidewall of the contact-opening portion 16.

Then, as shown in FIG. 9, a barrier metal (not shown in the figure) is formed in the contact-opening portion 16, followed by deposition of tungsten thereover. Then, the barrier metal and tungsten overlying the field on the interlayer-insulating film 13 are removed using the CMP method to form the contact-conductive film 15.

In this way, the semiconductor device of this embodiment is formed.

According to this embodiment, because the first polysilicon film 4 is left in the source-line contact LI part between the selection gates on the source side during gate processing, recessing of the element isolation-insulating film 23 caused by the etching in the contact-forming step is reduced. The element isolation-insulating film 23 is resultantly higher than the surface of the active region 21 so that junction leakage can be restrained.

On the other hand, for the contact CB, because the first polysilicon film 4 is removed by the etching during the selection-gate processing on the drain side, the element isolation-insulating film 23 becomes recessed in that region during the formation of the contact. Because the height of the element isolation-insulating film 23 becomes lower than the surface of the active region 21, it is possible to fully guarantee the contact area of the contact on the active region so that the contact resistance can be reduced.

### Other Embodiments

In addition to the aforementioned embodiment, the following modifications can be made.

A silicon oxide film is used as the first insulating film 9, the sidewall-insulating film 10, the second insulating film 11, and the third insulating film, while a silicon nitride film is used as the liner-insulating film 12. However, it is also possible to make appropriate exchanges or use different insulating films.

The present invention can also be applied to other circuit elements with contact openings formed on the first polysilicon film 4 in addition to the resistor as the element in the peripheral circuit region. For example, the present invention can also be applied to a capacitor that uses the first polysilicon film 4 and a semiconductor substrate as the electrodes which sandwich a gate-insulating film.

The present invention is applied to a NAND-type flash memory device as described above. However, the present invention can also be applied to a NOR-type flash memory device, an EEPROM, or other nonvolatile semiconductor storage devices. The present invention can be applied to semiconductor storage devices that constitute memory cells as one bit or as multiple bits.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device, comprising:
a semiconductor substrate;
a first pair of selection-gate electrodes including a first conductive layer and a second conductive layer;
a second pair of selection-gate electrodes;
a memory cell region formed in a matrix pattern between the first pair of selection-gate electrodes and the second pair of selection-gate electrodes;
an interlayer-insulating film covering the first pair of the selection-gate electrodes, the second pair of selection-gate electrodes, and the memory cell region,
a first contact provided between the first pair of selection gates; and
a second contact provided between the second pair of selection gates, wherein
the first contact penetrates through at least the interlayer-insulating film and the first conductive film layer and is connected on a surface of the semiconductor substrate;
an insulating film is formed on the first contact, and
the first contact is at least connected to the first conductive film layer via the insulating film on a side surface of the first contact.

2. The semiconductor storage device according to claim 1, wherein
the second contact penetrates through at least the interlayer-insulating film and is connected on the semiconductor substrate.

3. The semiconductor storage device according to claim 1, wherein
the first contact provided between the first pair of selection-gate electrodes is connected in common to source regions constituting transistors of the first pair of selection electrodes, and
the second contact provided between the second pair of selection-gate electrodes is connected in each of drain regions constituting transistors of the second pair of selection-gate electrodes.

4. The semiconductor storage device according to claim 1, wherein
a first width of the first contact is larger than a second width of the second contact.

5. The semiconductor storage device according to claim 1, wherein
the second conductive layer is provided on the first conductive layer.

6. The semiconductor storage device according to claim 5, wherein
a first distance between the first contact and the second conductive layer is larger than a second distance between the first contact and the first conductive layer.

7. The semiconductor storage device according to claim 6, wherein
a third distance between the second contact and the first conductive layer is same as a fourth distance between the second contact and the second conductive layer.

8. The semiconductor storage device according to claim 1, further comprising
a third contact reaching onto the first conductive layer, the third contact provided to a peripheral circuit included in the semiconductor storage device.

9. The semiconductor storage device according to claim 8, wherein
the third contact contacts a resistor included in the peripheral circuit.

10. The semiconductor storage device according to claim 8, wherein
a first width of the first contact is larger than a third width of the third contact.

11. A method of manufacturing a semiconductor storage device, comprising:
forming a gate-insulating film, a first conductive film, a first insulating film, a second conductive film and a second insulating film on a semiconductor substrate, the semiconductor substrate having a first region, a second region and a third region;
first etching the second insulating film, the second conductive film, the first insulating film and the first conductive film selectively in the first region;
second etching the second insulating film and the second conductive film selectively in the second region and the third region;
forming a fourth insulating film above the first region, the second region and the third region;
forming a first contact hole that penetrates the fourth insulating film and that connected to the semiconductor substrate in the first region;
forming a second contact hole that penetrates the fourth insulating film and the first insulating film and that connected to the first conductive film in the second region;
forming a third contact hole that penetrates the fourth insulating film, the first insulating film, the first conductive film and the gate-insulating film and that connected to the semiconductor substrate in the third region, a third width of the third contact hole being larger than a first width of the first contact hole and a second width of the second contact hole; and
the first contact hole, the second contact hole and the third contact hole formed in the same step.

12. The method according to claim 11, further comprising:
forming a fifth insulating film on each of sides of the first contact hole, the second contact hole and the third contact hole.

13. The method according to claim 11, further comprising:
forming a sidewall insulating film prior to the forming the fourth insulating film.

14. The method according to claim 11, further comprising:
forming a diffusion layer in the semiconductor substrate after the first etching.

15. The method according to claim 11, further comprising:
forming a diffusion layer in the semiconductor substrate after the second etching.
